(19) United States
(12) Patent Application Publication
(10) Pub. No.: US 2023/0054190 A1
(43) Pub. Date: Feb. 23, 2023

(54) SEMICONDUCTOR DEPOSITION METHOD AND SEMICONDUCTOR DEPOSITION SYSTEM

(71) Applicant: CHANGXIN MEMORY TECHNOLOGIES, INC., Hefei City, Anhui (CN)

(72) Inventors: Lifeng QIU, Hefei City, Anhui (CN); Lixia ZHANG, Hefei City, Anhui (CN)

(21) Appl. No.: 17/441,850

(22) PCT Filed: Jun. 21, 2021
(86) PCT No.: PCT/CN2021/101334

§ 371 Date: Sep. 22, 2021

(30) Foreign Application Priority Data
Aug. 14, 2020 (CN) 2020108220397.4

(51) Int. Cl. C23C 16/52; H01L 21/02; C23C 16/455

(52) U.S. Cl. CPC C23C 16/52; H01L 21/02274; C23C 16/45589; C23C 16/45565

(57) ABSTRACT

Disclosed a semiconductor deposition method and a semiconductor deposition system. The semiconductor deposition method includes providing a deposition apparatus, the deposition apparatus includes a spraying head for deposition; detecting whether a thickness defect exists in a deposited thin film or not, the thickness defect includes a thickness difference of the deposited thin film; acquiring at least one position where the thickness defect exists; and adjusting a structure of an air outlet panel in the spraying head based on the position of the thickness defect so as to adjust distances between air outlet holes in the air outlet panel and the deposited thin film.

### CROSS-REFERENCE TO RELATED APPLICATIONS

The present disclosure is a national stage entry of International Application No. PCT/CN2021/101334, filed on Jun. 21, 2021, which claims priority to Chinese Patent Application No. 202010820397.4, filed on Aug. 14, 2020, entitled “SEMICONDUCTOR DEPOSITION METHOD AND SEMICONDUCTOR DEPOSITION SYSTEM”. The entire contents of International Application No. PCT/CN2021/101334 and Chinese Patent Application No. 202010820397.4 are incorporated herein by reference.

### TECHNICAL FIELD

The present disclosure relates to, but is not limited to, a semiconductor deposition method and a semiconductor deposition system.

### BACKGROUND

In the manufacturing of an integrated circuit (IC), a chemical vapor deposition (CVD) process is primarily employed to form a thin layer or thin film on a semiconductor substrate (e.g., a wafer). In the chemical vapor deposition process, the semiconductor substrate is exposed to precursor gas which reacts on a surface of the semiconductor substrate and deposits a reaction product thereon.

In an actual deposition process, a thin film deposited on a semiconductor substrate with a flat surface generally has poor uniformity. The non-uniformity of the film deposited on the semiconductor substrate will affect the subsequent process, for example, the etching is non-uniform or the chemical grinding of the semiconductor substrate is non-uniform, which affects the quality of a semiconductor product finally.

### SUMMARY

The following is a summary of subject matter described in detail herein. This summary is not intended to limit the protection scope of the claims.

The present disclosure provides a semiconductor deposition method including: providing a deposition apparatus, the deposition apparatus includes a spraying head for deposition; detecting whether a thickness defect exists in a deposited thin film or not, the thickness defect includes a thickness difference of the deposited thin film; acquiring at least one position where the thickness defect exists; and adjusting a structure of an air outlet panel in the spraying head based on the position of the thickness defect so as to adjust distances between air outlet holes in the air outlet panel and the deposited thin film.

The present disclosure further provides a semiconductor deposition system.

The semiconductor deposition system according to the embodiment of the present disclosure includes a deposition apparatus and a control system. The deposition apparatus includes a spraying head, and a bearing platform configured to mount a semiconductor substrate. The control system includes a detection module and a control module. The detection module is disposed on the deposition apparatus, and is configured to detect whether a thickness defect exists in a deposited thin film on the semiconductor substrate or not. The control module is connected to the spraying head, and is configured to adjust a structure of an air outlet panel in the spraying head so as to adjust distances between air outlet holes in the air outlet panel and the deposited thin film.

Other aspects may be apparent upon reading and understanding the accompanying drawings and detailed description.

### BRIEF DESCRIPTION OF THE DRAWINGS

The accompanying drawings, which are incorporated in and constitute a part of this specification, illustrate embodiments of the present disclosure and, together with the description, serve to explain the principles of the embodiments of the present disclosure. In the accompanying drawings, like reference numerals are used to indicate like elements. The accompanying drawings in the following description are of some, but not all, embodiments of the present disclosure. Those of skill in the art may still derive other accompanying drawings from these accompanying drawings without creative efforts.

FIG. 1 is a schematic flowchart of a semiconductor deposition method provided by a first embodiment of the present disclosure.

FIGS. 2-5 are schematic structural diagrams of a deposition apparatus provided by the first embodiment of the present disclosure.

FIG. 6 is a schematic principle diagram of acquiring a thickness defect provided by the first embodiment of the present disclosure.

FIGS. 7-9 are schematic structural diagrams of a deposition apparatus provided by a second embodiment of the present disclosure.

FIG. 10 is a schematic flowchart of a semiconductor deposition method provided by a third embodiment of the present disclosure.

FIG. 11 is a schematic structural diagram of a semiconductor deposition system provided by a fourth embodiment of the present disclosure.

### DETAILED DESCRIPTION

A semiconductor deposition method and a semiconductor deposition system proposed by the present disclosure are described below with reference to the accompanying drawings and detailed description.

At present, in an actual deposition process, a thin film deposited on a semiconductor substrate with a flat surface generally has poor uniformity. The non-uniformity of the film deposited on the semiconductor substrate will affect the subsequent process, for example, the etching is non-uniform or the chemical grinding of the semiconductor substrate is non-uniform, which affects the quality of a semiconductor product finally.

The first embodiment of the present disclosure provides a semiconductor deposition method including: providing a deposition apparatus, the deposition apparatus includes a spraying head for deposition; detecting whether a thickness defect exists in a deposited thin film or not, the thickness defect includes a thickness difference of the deposited thin film; acquiring at least one position where the thickness defect exists; and adjusting a structure of an air outlet panel in the spraying head based on the position of the thickness defect so as to adjust distances between air outlet holes in the air outlet panel and the deposited thin film.

Various embodiments of the present disclosure will now be described in detail with reference to the accompanying drawings. However, those skilled in the art may understand that, in various embodiments of the present disclosure, numerous technical details are set forth for the reader to better understand the present disclosure. However, the technical solution claimed in the present disclosure may also be implemented even without these technical details and various changes and modifications based on the following embodiments. The following divisions of the various embodiments are for convenience of description and should not constitute any limitation on specific implementation of the present disclosure, and the various embodiments may be combined with and referenced to each other if there is no conflict.

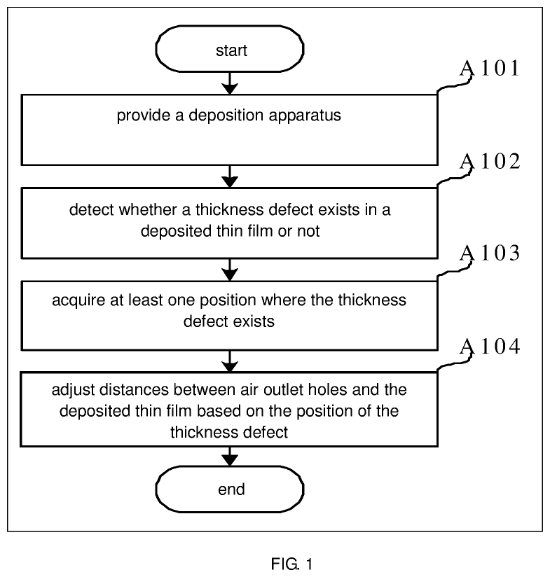

FIG. 1 is a schematic flowchart corresponding to all steps of the semiconductor deposition method provided by the first embodiment of the present disclosure. The semiconductor deposition method of this embodiment is described in detail below.

Referring to FIG. 1, the semiconductor deposition method includes the following steps:

Step A101, the deposition apparatus is provided. The deposition apparatus includes the spraying head for deposition.

Generally speaking, a plane where air outlet holes of a spraying head of a traditional chemical vapor deposition apparatus are located is a plane parallel to the semiconductor substrate, and the plane where the air outlet holes of the spraying head are located is right opposite to the semiconductor substrate. Gas exhausted by the spraying head reacts on the surface of the semiconductor substrate, and a reaction product is deposited on the surface of the semiconductor substrate. However, a thin film formed by deposition on the surface of the semiconductor substrate is thin in middle and thick in edge.

In this embodiment, atmospheric pressure chemical vapor deposition (APCVD) apparatus is taken as an example. In addition, plasma enhanced chemical vapor deposition (PECVD) apparatus or metal organic chemical vapor deposition (MOCVD) apparatus may also be used. Through the special shape of the spraying head and the corresponding deposition method to improve the uniformity of the deposited film.

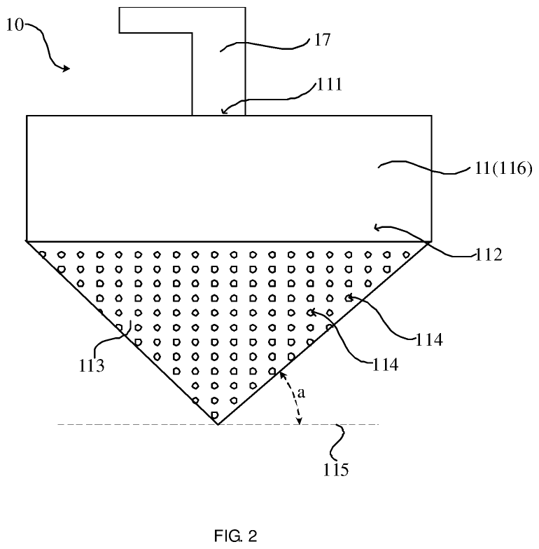

Referring to FIG. 2, FIG. 2 is a schematic structural diagram of the deposition apparatus provided by this embodiment of the present disclosure. The spraying head 10 includes a shell 11. The shell 11 includes a first end and a second end disposed oppositely. The first end and the second end are an upper side portion and a lower side portion of the shell 11 as shown in FIG. 2. The first end of the shell 11 is provided with an air inlet 111 connected to an air inlet pipe 17, and the second end of the shell 11 is provided with an air outlet panel 113. A panel surface of the air outlet panel 113 is provided with a plurality of air outlet holes 114, and a middle portion of the panel surface of the air outlet panel 113 is farer away from the first end compared with an edge portion.

When the above spraying head 10 performs chemical vapor deposition operation on the semiconductor substrate, reactant gas enters an inner cavity of the shell 11 through a gas inlet 111, and is exhausted outwards through the air outlet holes 114 of the air outlet panel 113, blown to the semiconductor substrate and deposited on the surface of the semiconductor substrate to form the deposited thin film. Because the middle portion of the air outlet panel 113 is farer away from the first end compared with the edge portion, the middle portion of the air outlet panel 113 is closer to the semiconductor substrate compared with the edge portion of the air outlet panel 113, so that during deposition, more particles are deposited in the middle portion, and particles deposited from the middle portion to the edge area are gradually reduced. Compared with a traditional flat air outlet panel, the thickness of the middle portion of the thin film acquired by deposition on the semiconductor substrate can be relatively increased, and therefore the uniformity of the thin film acquired by deposition on the surface of the semiconductor substrate is improved.

In this embodiment, the air outlet panel 113 is of a cone structure or a cone frustum structure. Thus, all portions of the thin film acquired by deposition on the surface of the semiconductor substrate are relatively uniform. When the spraying head 10 performs chemical vapor deposition operation right opposite to the semiconductor substrate, a plane, parallel to the semiconductor substrate, on the spraying head 10 is selected as a reference plane 115. Specifically, the angle of the air outlet panel 113 with the cone structure can be adjusted, and an included angle a formed between a conical surface of the air outlet panel 113 and the reference plane 115 can be adjusted. When the included angle a is larger, this means that the middle portion of the air outlet panel 113 is closer to the semiconductor substrate compared with the edge portion. When the included angle a is smaller, it is shown that the middle portion of the air outlet panel 113 is less close to the semiconductor substrate compared with the edge portion.

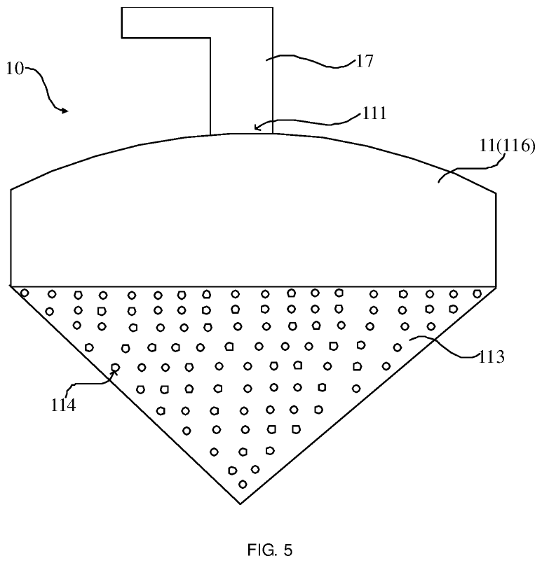

It should be noted that in other embodiments, the air outlet panel may be composed of a plurality of parallel plates. The structure of the air outlet panel is not specifically limited in this embodiment. In addition, referring to FIG. 5, a main body structure 116 of the shell 11 may be a cylinder, a hemisphere or a structure formed by combining a cylinder and a hemisphere. The main body structure 116 refers to a structure formed after the air outlet panel 113 is removed from the shell 11. A projection of the shell 11 on the semiconductor substrate 30 is matched with a shape of the surface of the semiconductor substrate 30. In this way, a thin film can be acquired by uniform deposition on all portions of the surface of the semiconductor substrate 30. Certainly, the main body structure 116 of the shell 11 is not limited to the above structure, further may be other irregular structures, which are not described in detail herein.

Continuing with FIG. 1, step A102, whether a thickness defect exists in the deposited thin film or not is detected. The thickness defect includes a thickness difference of the deposited thin film.

It should be noted that in this embodiment, the detection of the thickness defect in the deposited thin film is realized during the deposition of the semiconductor substrate. The structure of the air outlet panel in the spraying head is changed at any time according to the thickness of the deposited thin film. In other embodiments, the thickness defect of the deposited thin film may also be measured through a measuring machine, and the structure of the air outlet panel in the spraying head is fed back and adjusted according to the measurement result.

In exemplary implementation, step A102 includes sub-step A102-1 of detecting thicknesses of to-be-detected areas in the deposited thin film and sub-step A102-2 of judging whether the thickness defect exists in the deposited thin film or not based on the thicknesses of the to-be-detected areas.

Sub-step A102-1, the thicknesses of the to-be-detected areas in the deposited thin film are detected.

The to-be-detected areas include a first detection area which is a first distance away from a center position of the deposited thin film and a second detection area which is a second distance away from the center position of the deposited thin film, and the second distance is larger than the first distance. In this embodiment, the first detection area is disposed at the center position of the deposited thin film, and the second detection area is disposed at an edge position of the deposited thin film.

In exemplary implementation, sensors may be disposed at positions, corresponding to the first detection area and the second detection area, of the air outlet panel to obtain thicknesses of the deposited thin film in the first detection area and the second detection area.

It should be noted that in other embodiments, a plurality of detection areas, such as a third detection area and a fourth detection area, may be included. The thickness of each position of the deposited thin film may be comprehensively and accurately acquired through the detection areas disposed at different radius positions. The conclusion judged subsequently that whether the thickness defect exists in the deposited thin film or not is more convincing.

Sub-step A102-2, whether the thickness defect exists in the deposited thin film or not is judged based on the thicknesses of the to-be-detected areas.

Whether the thickness defect exists in the deposited thin film or not is judged based on the thicknesses of the deposited thin film detected in the first detection area and the second detection area.

In this embodiment, the first detection area is disposed at the center position of the deposited thin film, and the second detection area is disposed at the edge position of the deposited thin film. Whether the thickness defect exists in the deposited thin film or not is judged based on the thicknesses of the deposited thin film detected in the first detection area and the second detection area, i.e. based on a middle thickness and an edge thickness of the deposited thin film.

In exemplary implementation, whether a thickness difference of each to-be-detected area exceeds a preset threshold value range or not is judged according to the acquired thicknesses of the to-be-detected areas. If yes, it indicates that a higher position and a lower position of the deposited thin film have a large thickness difference, that is, the thickness defect exists in the deposited thin film.

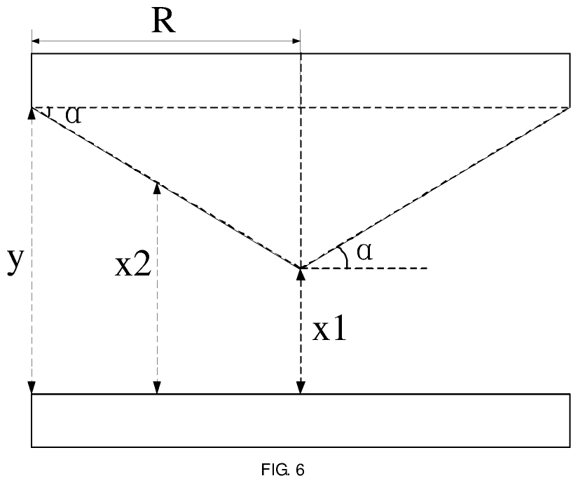

Referring to FIG. 6, the principle is introduced with the circular deposited thin film and the conical air outlet panel as an example. Specific description will be carried out below with reference to following calculation formulas:

x1+R tan α=y (1)

x0=x1−x1′ (2)

α′=Δα+α (3)

x0=y−R tan α′−x1′ (4)

y0=y−y′ (5)

Δ=|y0−x0| (6)

Where, a radius of a body of the air outlet panel is R. Because the body of the air outlet panel is unchanged, R is a constant value. A distance from the edge position of the air outlet panel to the machine is y. Because the edge position of the air outlet panel cannot move, y is a constant value. In an initial state, a distance from the middle position of the air outlet panel to the machine is x1. Because the middle part of the air outlet panel can move, x1 is a variable. An inclination angle of the air outlet panel is α.

In the initial state, numeral values y and x1 read by the sensors at the edge position and the middle position of the air outlet panel are acquired, and the inclination angle a of the air outlet panel is calculated out based on the formula (1).

After thin film deposition, if the angle of the air outlet panel is not adjusted, numeral values y′ and x1′ read by the sensors at the edge position and the middle position of the air outlet panel are acquired. At this time, thicknesses y0 and x0 of the edge position and the middle position of the deposited thin film can be calculated out according to the formulas (2) and (5). After thin film deposition, if the angle of the air outlet panel is adjusted, and an adjusted angle is Δα, at this time, an actual inclination angle α′ of the air outlet panel is calculated out according to the formula (3). Then, the thicknesses y0 and x0 of the edge position and the middle position of the deposited thin film are calculated according to the formulas (4) and (5).

Then the thicknesses difference Δ of the to-be-detected areas in the deposited thin film are calculated according to the formula (6).

It should be noted that in other embodiments, the third detection area or the like is included besides the first detection area and the second detection area, and the thickness detection data x2 in the third detection area is subjected to data detection similar to xl, the detailed flow of which is the same as above and will not be described in more detail herein.

Step A103, at least one position with the thickness defect is acquired.

A detection area with the thickness defect of the deposited thin film is judged based on the thickness difference of the deposited thin film. The position of a sensor corresponding to the detection area is acquired, and therefore the position of the thickness defect is acquired.

Step A104, the distance between the air outlet holes and the deposited thin film is adjusted based on the position of the thickness defect.

The structure of the air outlet panel 113 in the spraying head is adjusted based on the position of the thickness defect so as to adjust the distances between the air outlet holes 114 in the air outlet panel 113 and the deposited thin film. In this embodiment, the middle portion of the air outlet panel 113 is adjusted to move towards a direction close to or away from the deposited thin film to adjust the distances between the air outlet holes 114 in the air outlet panel 113 and the deposited thin film.

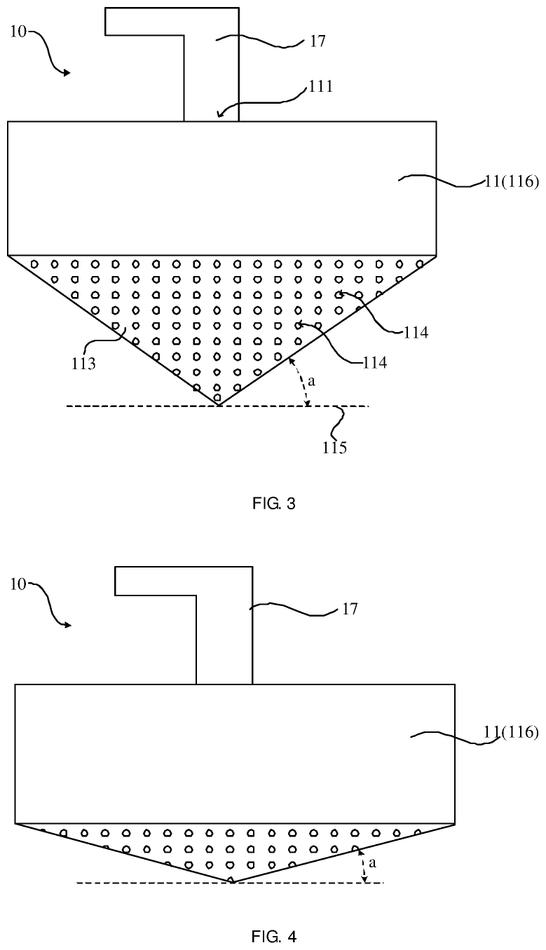

Referring to FIG. 3 and FIG. 4, the air outlet panel 113 is adjustably disposed at the second end of the shell 11. When the air outlet panel 113 is adjustably disposed at the second end of the shell 11, the distance between the air outlet holes 114 in the air outlet panel 113 with different inclination angles and the deposited thin film can be adjusted according to actual situations.

The middle portion of the air outlet panel 113 with different inclination angles is away from the first end by different degrees relative to the edge portion, i.e. close to the surface of the semiconductor substrate by different degrees during chemical vapor deposition. When it is required to increase the thickness of the middle portion of the thin film acquired by deposition on the surface of the semiconductor substrate, the air outlet panel 113 with the middle portion farer away from the first end relative to the edge portion may be adjusted, that is, the middle portion of the air outlet panel 113 is adjusted to be more convex outwards, so that the middle portion of the air outlet panel 113 is closer to the surface of the semiconductor substrate 30, and the thickness of the middle portion of the thin film acquired by deposition on the surface of the semiconductor substrate is relatively increased. On the contrary, when it is required to decrease the thickness of the middle portion of the thin film acquired by deposition on the surface of the semiconductor substrate, the air outlet panel 113 with the middle portion less far away from the first end relative to the edge portion may be adjusted, that is, the middle portion of the air outlet panel 113 is adjusted to be less convex outwards, so that the middle portion of the air outlet panel 113 is less close to the surface of the semiconductor substrate, and the thickness of the middle portion of the thin film acquired by deposition on the surface of the semiconductor substrate is relatively decreased.

It should be noted that, in this embodiment, detection of existing or not of the thickness defect in the deposited thin film in step A102 includes real-time detection and timing detection. Correspondingly, adjustment of the distance between the air outlet holes and the deposited thin film in step A104 also includes real-time adjustment and timing adjustment. Real-time adjustment means that during film thin deposition, the inclination angle α of the air outlet panel 113 is adjusted in real time according to the detected thickness difference Δ. The timing detection is used for a sectional deposition mode, that is, a film deposition process is divided into a plurality of stages, a part of thin film is deposited at each stage, and the relation between the inclination angle α of the air outlet panel and the thickness variation of the deposited thin film is acquired by collecting deposition data. Assuming that h=K*α+ψ, h is the variation value of the corresponding thickness after the angle α is adjusted. After each stage of deposition is performed, the inclination angle α of the air outlet panel 113 during the next stage of deposition is improved by detecting the thickness difference of the deposited thin film, so that the uniformity of the thickness of the deposited thin film is improved. In other embodiments, the thickness of the deposited thin film after deposition can also be detected through the measuring machine, the thickness difference h of the deposited thin film is measured through the measuring machine, and then the inclination angle α of the air outlet panel in the spraying head is adjusted according to the relation between the thickness difference h and the angle α, so that the uniformity of the subsequently formed deposited thin film is realized.

It should be noted that this embodiment improves the morphology of the deposited thin film by adjusting the distance of the middle position of the air outlet panel 113 relative to the edge portion to avoid the thickness defect of the deposited thin film that the edge is high and the middle is low, i.e. by adjusting at least one air outlet hole corresponding to the at least one position of the thickness defect to be close to or away from the deposited thin film. In other embodiments, the middle position of the air outlet panel may also be fixed, and the morphology of the deposited thin film is improved by adjusting the distance of the edge portion of the air outlet panel relative to the middle position, i.e. by adjusting other air outlet holes except the air outlet holes corresponding to the thickness defect position to be close to or away from the deposited thin film.

Whether the thickness difference exists in the deposited thin film or not is judged by detecting whether the thickness defect exists on the deposited thin film or not. The positions of the air outlet holes in the air outlet panel are correspondingly adjusted according to the position of the thickness defect. Therefore, the thickness difference in the deposited thin film is relieved, and the thickness uniformity of the deposited thin film on the semiconductor substrate is effectively improved.

The above steps are divided merely just for clear description, and the steps can be combined into one step or some steps are split and decomposed into a plurality of steps when implemented. As long as the same logical relationship is included, the steps are all within the scope of protection of the present patent. It is within the scope of protection of this patent to add insignificant modifications to the process or to introduce insignificant designs without changing the core design of its process.

The second embodiment of the present disclosure relates to a semiconductor deposition method. In contrast to the first embodiment, a structure of a spraying head in a deposition apparatus and a way of adjusting the spraying head applied in this embodiment are different from those in the first embodiment.

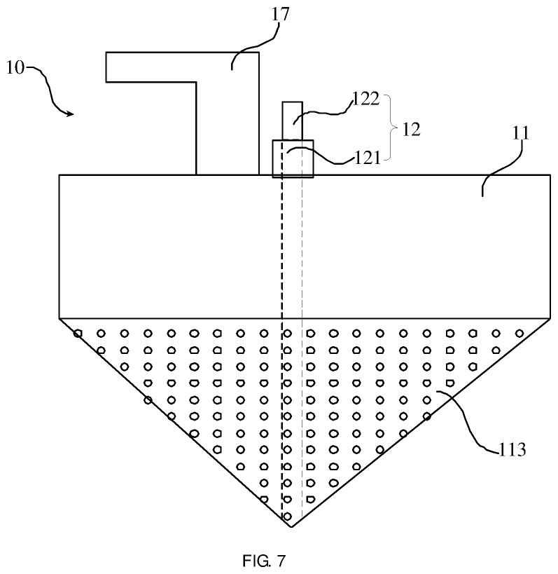

Referring to FIGS. 7-9, the semiconductor deposition method provided by this embodiment will be described in detail below with reference to the accompanying drawings, and the parts which are the same or corresponding to the first embodiment will not described in detail below.

This embodiment provides two methods for adjusting an air outlet panel, specifically as follows:

Method 1: a pushing assembly is disposed in a middle of the air outlet panel. A length of the pushing assembly is adjusted to move the middle portion of the air outlet panel towards a direction close to or away from a deposited thin film.

In exemplary implementation, referring to FIG. 7, the deposition apparatus further includes a driving assembly 12. The air outlet panel 113 is a deformable plate. The driving assembly 12 is disposed on the shell 11. The driving assembly 12 is configured to drive a middle portion of the deformable plate to move telescopically in a direction away from or close to a first end. Specifically, the deformable plate, for example, an elastic panel or a flexible material plate is not limited here as long as the deformable plate can be correspondingly deformed under the urging of the driving assembly 12. Taking the deformable plate being the elastic panel as an example for illustration, the middle portion of the deformable plate is driven to move towards a direction far away from the first end by the driving assembly 12, so that the deformable plate is deformed. An included angle a formed between a panel surface of the air outlet panel 113 and a reference plane 115 is increased, and the degree by which the middle portion of the panel surface of the air outlet panel 113 is far away from the first end relative to the edge portion can be increased. On the contrary, when the driving assembly 12 is retracted, the deformable plate is restored under the action of elastic force, and the included angle a formed between the panel surface of the air outlet panel 113 and the reference plane 115 is reduced.

In exemplary implementation, the driving assembly 12 includes a nut 121 disposed at the first end, and a screw rod 122 matched with the nut 121. One end of the screw rod 122 is located outside the shell 11, and the other end of the screw rod 122 stretches into the shell 11 and is connected to the middle portion of the air outlet panel 113. In one example, different from the above combined structure that the nut 121 and the screw rod 122 are matched, the driving assembly 12 includes a push-pull rod. The push-pull rod penetrates through the shell 11 to stretch into the shell 11. An end of the push-pull rod is connected to the middle portion of the air outlet panel 113. As the other example, different from the above combined structure that the nut 121 and the screw rod 122 are matched, the driving assembly 12 includes a telescopic adjusting rod disposed in the shell 11, and an end of the telescopic adjusting rod is connected to the middle portion of the air outlet panel 113.

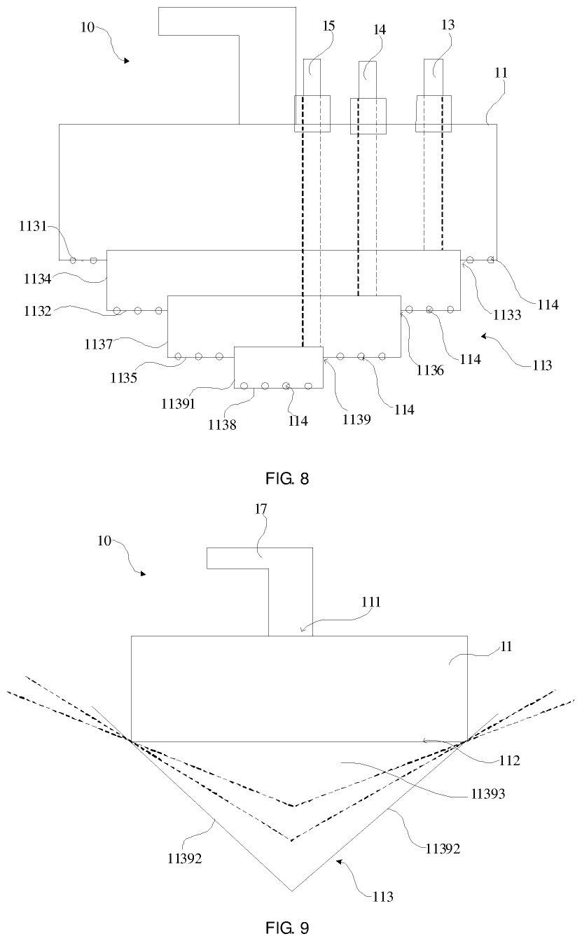

In exemplary implementation, referring to FIG. 8, the driving assembly includes a first pushing assembly 13, a second pushing assembly 14 and a third pushing assembly 15. The first pushing assembly 13, the second pushing assembly 14 and the third pushing assembly 15 are disposed on the shell 11. The air outlet panel 113 includes a peripheral panel 1131 and a first middle panel 1132 located in a middle area of the peripheral panel 1131. The peripheral panel 1131 is fixedly disposed at a second end of the shell 11, and a middle portion of the peripheral panel 1131 is provided with a first movable opening 1133. A first windshield sleeve 1134 wraps around an edge of the first middle panel 1132. The first windshield sleeve 1134 is movably disposed in the first movable opening 1133. The first pushing assembly 13 is connected to the first middle panel 1132 for pushing the first middle panel 1132 to be away from or close to the first end. The air outlet panel 113 further includes a second middle panel 1135. A middle portion of the first middle panel 1132 is provided with a second movable opening 1136. A second windshield sleeve 1137 wraps around an edge of the second middle panel 1135. The second windshield sleeve 1137 is movably disposed in the second movable opening 1136. The second pushing assembly 14 is connected to the second middle panel 1135 for pushing the second middle panel 1135 to be away from or close to the first end. In this way, the uniformity of the thin film acquired by deposition on a surface of a semiconductor substrate 30 can be improved. The air outlet panel 113 further includes a third middle panel 1138. A middle portion of the second middle panel 1135 is provided with a third movable opening 1139. A third windshield sleeve 11391 wraps around an edge of the third middle panel 1138. The third windshield sleeve 11391 is movably disposed in the third movable opening 1139. The third pushing assembly 15 is connected to the third middle panel 1138 for pushing the third middle panel 1138 to be away from or close to the first end.

In this embodiment, in order to ensure a good moving effect of the first windshield sleeve at the first movable opening 1133, for example, a guide rib (not shown in drawings) is disposed on an outer wall of the first windshield sleeve, and for example, a concave portion (not shown in drawings) in sliding fit with the guide rib is disposed on an opening wall of the first movable opening 1133. In addition, in another embodiment, the first windshield sleeve is formed as a telescopic sleeve body, one end of the sleeve body is connected to the opening wall of the first movable opening 1133, and the other end of the sleeve body is circumferentially disposed around the edge of the first middle panel 1132. When the first pushing assembly 13 pushes the first middle panel 1132, the sleeve body extends or shortens accordingly. It should be noted that the second pushing assembly 14 and the third pushing assembly 15 are disposed similar to the first pushing assembly 13 and will not be described in detail herein. The second windshield sleeve 1137 and the third windshield sleeve 11391 are disposed similar to the first windshield sleeve 1134 and will not be described in detail herein.

In the example, parallel plates are taken as examples for specific introduction. The structure that three parallel plates make the middle portion of the air outlet panel move towards a direction close to or away from a deposited thin film through the three pushing assemblies. In other examples, the number of the parallel plates may be not limited to three, and may be two or more than three parallel plates. It should be noted that it is advantageous to improve the uniformity of the thin film acquired by deposition on the surface of the semiconductor substrate 30 when the number of the middle panels of the air outlet panel 113 is larger and the middle panels are sequentially sleeved from the periphery to the middle. The number of the middle panels of the air outlet panel 113 is not limited here to the first middle panel 1132, the second middle panel 1135, and the third middle panel 1138, and there may be a fourth middle panel, a fifth middle panel, etc., which may be specifically disposed as required. Further, the shape of each panel is not limited to a rectangular shape, and is applicable to other shapes such as a cone or a hemisphere.

Method 2: a connecting portion is disposed in the middle of the air outlet panel, and a sliding component is disposed at the edge of the air outlet panel. The air outlet panel is adjusted to slide based on the sliding component to move the middle portion of the air outlet panel towards the direction close to or away from the deposited thin film.

In exemplary embodiment, referring to FIG. 9, two dashed lines in FIG. 9 illustrate two specific positions to which the air outlet panel 113 may be adjusted. In this embodiment, the air outlet panel 113 includes two rotating panels 11392 and two windshield flexible plates 11393. The second end of the shell 11 is provided with an air outlet 112. One ends of the two rotating panels 11392 are rotatably connected through the connecting portion, and the other ends of the rotating panels 11392 are in sliding fit with the second end of the shell 11 through the sliding component. One windshield flexible plate 11393 is connected to one side and second ends of the two rotating panels 11392, respectively, and the other windshield flexible plate 11393 is connected to the other sides and the second ends of the two rotating panels 11392, respectively. The two windshield flexible plates 11393 and two rotating panels 11392 enclose the air outlet 112. Air outlet holes 114 are formed in the rotating panels 11392. The flexible plates 11393 may or may not be provided with air holes 114, which is not limited herein. Thus, by adjusting the angle between the two rotating panels 11392, it is possible to adjust the degree to which a connection portion of the two rotating panels 11392 (corresponding to the middle portion of the air outlet panel 113) is far away from the first end relative to the edge portion.

Whether the thickness difference exists in the deposited thin film or not is judged by detecting whether the thickness defect exists on the deposited thin film or not. The positions of the air outlet holes in the air outlet panel are correspondingly adjusted according to the position of the thickness defect. Therefore, the thickness difference in the deposited thin film is relieved, and the thickness uniformity of the deposited thin film on the semiconductor substrate is effectively improved.

The above steps are divided merely just for clear description, and the steps can be combined into one step or some steps are split and decomposed into a plurality of steps when implemented. As long as the same logical relationship is included, the steps are all within the scope of protection of the present patent. It is within the scope of protection of this patent to add insignificant modifications to the process or to introduce insignificant designs without changing the core design of its process.

The third embodiment of the present disclosure relates to a semiconductor deposition method. Different from the first embodiment, this embodiment is further used to acquire a thickness distribution diagram after detecting the thickness of the deposited thin film, and to judge whether a thickness defect exists in the deposited thin film or not according to the thickness distribution diagram, which is higher in detection accuracy.

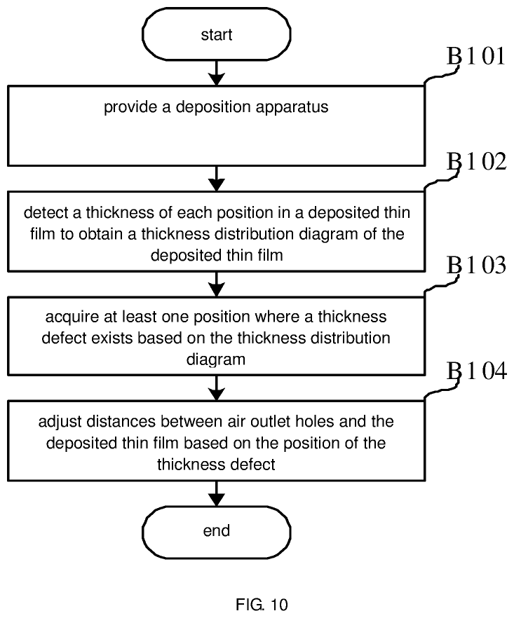

Referring to FIG. 10, the semiconductor deposition method provided by this embodiment will be described in detail below with reference to the accompanying drawings, and the parts which are the same or corresponding to the first embodiment will not be described in detail below.

The semiconductor deposition method includes the following steps:

Step B101, a deposition apparatus is provided.

Step B102, a thickness of each position in a deposited thin film is detected to obtain a thickness distribution diagram of the deposited thin film. Specifically, thicknesses of positions, corresponding to air outlet holes, in the deposited thin film are detected, and the thickness distribution diagram is acquired based on the thicknesses of the positions, corresponding to the air outlet holes, in the deposited thin film and distribution of the air outlet holes.

In this embodiment, sensors for detecting distances are disposed nearby the air outlet holes, respectively, and are configured to measure the thicknesses of the positions, corresponding to the air outlet holes respectively, of the deposited thin film. By disposing the plurality of sensors, the thickness of each position of the deposited thin film can be accurately acquired.

Step B103, at least one position where the thickness defect exists is acquired based on the thickness distribution diagram. The position of the thickness defect acquired through the thickness distribution diagram is more accuracy.

Step B104, a distance between the air outlet holes and the deposited thin film is adjusted based on the position of the thickness defect.

It should be noted that in this embodiment, the method further includes adjusting a structure of an air outlet panel in a spraying head to adjust the air outlet holes in the air outlet panel to ventilate or not to ventilate. If a defect appears at a local part of the deposited thin film, that is, the difference between the thickness of the local part and the thickness of other parts is too large, even if the distance between the air outlet holes and the deposited thin film is adjusted, the thickness difference of the local area is still difficult to compensate. At the moment, the thickness defect of the local position can be more conveniently relieved by closing air outlet holes at corresponding positions.

Whether the thickness difference exists in the deposited thin film or not is judged by detecting whether the thickness defect exists on the deposited thin film or not. The positions of the air outlet holes in the air outlet panel are correspondingly adjusted according to the position of the thickness defect. Therefore, the thickness difference in the deposited thin film is relieved, and the thickness uniformity of the deposited thin film on the semiconductor substrate is effectively improved.

The above steps are divided merely just for clear description, and the steps can be combined into one step or some steps are split and decomposed into a plurality of steps when implemented. As long as the same logical relationship is included, the steps are all within the scope of protection of the present patent. It is within the scope of protection of this patent to add insignificant modifications to the process or to introduce insignificant designs without changing the core design of its process.

Because the first embodiment and this embodiment correspond to each other, this embodiment and the first embodiment can be mutually matched for implementation. The related technical details mentioned in the first embodiment are still valid in this embodiment, and the technical effects that can be achieved in the first embodiment can also be achieved in this embodiment. In order to reduce repetition, a detailed description will not be repeated here. Correspondingly, the related technical details mentioned in this embodiment may also be applied in the first embodiment.

The fourth embodiment of the present disclosure relates to a semiconductor deposition system.

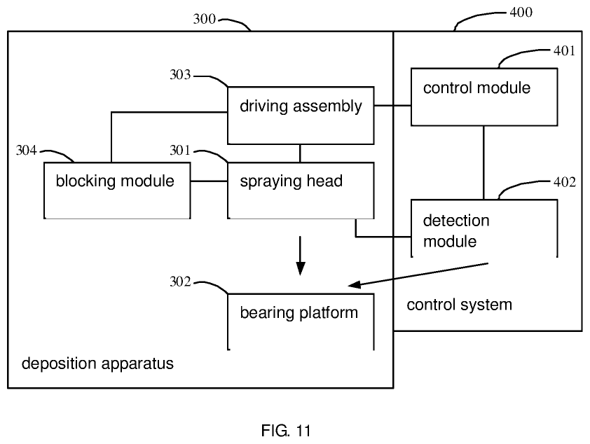

Referring to FIG. 11, the semiconductor deposition system provided by this embodiment will be described in detail below with reference to the accompanying drawings, and the parts which are the same or corresponding to the first embodiment will not be described in detail below.

The semiconductor deposition system includes a deposition apparatus 300 and a control system 400.

The deposition apparatus 300 includes a spraying head 301, and a bearing platform 302 configured to mount a semiconductor substrate. The control system 400 includes a detection module 402 and a control module 401. The detection module 402 is disposed on the deposition apparatus 300, and is configured to detect whether a thickness defect exists in a deposited thin film on the semiconductor substrate or not. The control module 401 is connected to the spraying head 301, and is configured to adjust a structure of an air outlet panel in the spraying head 301 so as to adjust distances between air outlet holes in the air outlet panel and the deposited thin film.

When the above deposition apparatus 300 performs chemical vapor deposition operation on the semiconductor substrate, reactant gas enters an inner cavity of a shell through a gas inlet, and is exhausted outwards through the air outlet holes of the air outlet panel, blown to the semiconductor substrate and deposited on the surface of the semiconductor substrate to form a deposited thin film. Because a middle portion of the air outlet panel is farer away from a first end compared with an edge portion, the middle portion of the air outlet panel is closer to the semiconductor substrate compared with the edge portion of the air outlet panel. Compared with a traditional flat air outlet panel, the thickness of a middle portion of the thin film acquired by deposition on the semiconductor substrate can be relatively increased, and therefore the uniformity of the thin film acquired by deposition on the surface of the semiconductor substrate is improved.

The deposition apparatus 300 may be a plasma-enhanced chemical vapor deposition (PECVD) apparatus, an atmospheric pressure chemical vapor deposition (APCVD) apparatus or a metal organic chemical vapor deposition (MOCVD) apparatus.

In exemplary implementation, the bearing platform 302 is embodied as a suction cup having a diameter substantially the same as or similar to a diameter of the spraying head 301 and being capable of moving vertically along an axis. The movable bearing platform 302 is configured to adjust the position thereof in a vacuum chamber. A heating system or a cooling system may be disposed in the bearing platform 302 to heat or cool the semiconductor substrate and/or configured to heat or cool a wall of the vacuum chamber. Plasma-enhanced chemical vapor deposition is a process which deposits thin films of various materials on the semiconductor substrate at a lower temperature than standard chemical vapor deposition (CVD). A direct current (DC) power supply or a radio frequency (RF) power supply may be attached to the vacuum chamber to generate a plasma in the plasma-enhanced chemical vapor deposition process. In the plasma-enhanced chemical vapor deposition process, deposition is realized by introducing reactant gas between parallel electrodes (an RF energized electrode or a direct current electrode and a grounded electrode). Alternatively, the chamber may be provided with a coil to generate higher-density inductively coupled plasma. In either case, the spraying head 301 of the above embodiment plays an important role in the uniformity of the acquired film. The capacitive coupling between the electrode and the electrode excites the reactant gas into the plasma, which initiates a chemical reaction and causes that reaction products are deposited on the semiconductor substrate. Depending on particular film requirements, the semiconductor substrate placed on the ground electrode may be heated to 250□ to 350□.

In contrast, standard chemical vapor deposition without plasma excitation may require higher temperatures, such as heating to a range between 600□ and 800□. Since the temperature of chemical vapor deposition possibly damages a manufactured device, lower deposition temperature is critical in many applications. Films commonly deposited using plasma-enhanced chemical vapor deposition are silicon nitride (SiN), silicon oxide (SiO), silicon oxynitride (SiON), silicon carbide (SiC), and amorphous silicon (α-Si). Silane (SiH) is combined with an oxygen source gas to form silicon dioxide, or silane is combined with a nitrogen source gas to form silicon nitride. In some embodiments, an oxide layer (i.e., a plasma enhanced TEOS (PETEOS) process) is formed using a tetra ethyl ortho silicate (TEOS) material by the plasma-enhanced chemical vapor deposition process. By plasma ignition, a high deposition rate is acquired from ethyl orthosilicate/oxygen.

In this embodiment, the control module 401 is connected to the spraying head 301 through a driving assembly 303. The control module 401 is configured to transmit a control signal to the driving assembly 303, and the driving assembly adjusts the structure of the air outlet panel in the spraying head based on the control signal, so as to adjust the distances between the air outlet holes in the air outlet panel and the deposited thin film. In one example, the driving assembly 303 adopts a piezoelectric ceramic driver, which has the advantages of small volume, large bearing capacity, fast response speed, high displacement resolution, low electromagnetic noise, no heat, etc.

In exemplary implementation, the deposition apparatus 300 further includes a blocking module 304. The blocking module 304 is connected to the driving assembly 303 and the spraying head 301. The driving assembly 303 is configured to control the blocking module to block the air outlet holes in the spraying head 301 or not based on the control signal.

The structure of the air outlet panel is adjusted according to the judgment result of the thickness of the deposited thin film, so as to adjust the positions of the air outlet holes in the air outlet panel, so that the thickness of the deposited thin film is improved, and the thickness uniformity of the deposited thin film is improved.

Other embodiments of the present disclosure will be apparent to those skilled in the art from consideration of the specification and practice of the present disclosure. The present disclosure is intended to cover any variations, uses, or adaptations of the present disclosure following the general principles of the present disclosure and including common general knowledge or customary technical means in the art not disclosed in the present disclosure. The specification and embodiments are considered to be exemplary only, and the true scope and spirit of the present disclosure are indicated by the following claims.

It should to be understood that the present disclosure is not limited to the precise structure described above and illustrated in the accompanying drawings, and various modifications and changes may be made without departing from the scope thereof. The scope of the present disclosure is limited only by the appended claims.

### INDUSTRIAL APPLICABILITY

According to the semiconductor deposition method and the semiconductor deposition system provided by the present disclosure, the present disclosure judges whether the thickness difference exists in the deposited thin film or not by detecting whether the thickness defect exists in the deposited thin film or not, and correspondingly adjusts positions of the air outlet holes in the air outlet panel according to the position of the thickness defect, so that the thickness difference occurring in the deposited thin film is relieved, and the thickness uniformity of the deposited thin film on the semiconductor substrate is effectively improved.

1. A semiconductor deposition method, comprising:
providing a deposition apparatus, the deposition apparatus comprises a spraying head for deposition;
detecting whether a thickness defect exists in a deposited thin film or not, the thickness defect comprises a thickness difference of the deposited thin film;
acquiring at least one position where the thickness defect exists; and
adjusting a structure of an air outlet panel in the spraying head based on the position of the thickness defect so as to adjust distances between air outlet holes in the air outlet panel and the deposited thin film.

2. The semiconductor deposition method according to claim 1, wherein the detecting whether the thickness defect exists in the deposited thin film or not comprises:
detecting thicknesses of to-be-detected areas in the deposited thin film; and
judging whether the thickness defect exists in the deposited thin film or not based on the thicknesses of the to-be-detected areas.

3. The semiconductor deposition method according to claim 2, wherein the judging whether the thickness defect exists in the deposited thin film or not based on the thicknesses of the to-be-detected areas comprises:
the to-be-detected areas comprises a first detection area which is a first distance away from a center position of the deposited thin film and a second detection area which is a second distance away from the center position of the deposited thin film, wherein the second distance is larger than the first distance; and
judging whether the thickness defect exists in the deposited thin film or not based on the thicknesses of the deposited thin film detected in the first detection area and the second detection area.

4. The semiconductor deposition method according to claim 3, wherein the first detection area is disposed at the center position of the deposited thin film, and the second detection area is disposed at an edge position of the deposited thin film.

5. The semiconductor deposition method according to claim 1, wherein the adjusting the structure of the air outlet panel in the spraying head so as to adjust the distances between the air outlet holes in the air outlet panel and the deposited thin film comprises:
adjusting a middle portion of the air outlet panel to move towards a direction close to or away from the deposited thin film.

6. The semiconductor deposition method according to claim 1, wherein the detecting whether the thickness defect exists in the deposited thin film or not comprises:
detecting a thickness of each position in the deposited thin film to obtain a thickness distribution diagram of the deposited thin film; and
judging whether the thickness defect exists in the deposited thin film or not based on the thickness distribution diagram.

7. The semiconductor deposition method according to claim 6, wherein the detecting the thickness of each position in the deposited thin film to obtain the thickness distribution diagram of the deposited thin film comprises:
detecting thicknesses of positions, corresponding to the air outlet holes, in the deposited thin film; and
acquiring the thickness distribution diagram based on the thicknesses of the positions, corresponding to the air outlet holes, in the deposited thin film and distribution of the air outlet holes.

8. The semiconductor deposition method according to claim 7, further comprising: adjusting the structure of the air outlet panel in the spraying head to adjust the air outlet holes in the air outlet panel to ventilate or not to ventilate.

9. The semiconductor deposition method according to claim 1, wherein the adjusting the structure of the air outlet panel in the spraying head comprises: adjusting at least one air outlet hole corresponding to the at least one position of the thickness defect to be close to or away from the deposited thin film.

10. A semiconductor deposition system, wherein the semiconductor deposition system comprises a deposition apparatus and a control system;
the deposition apparatus comprises a spraying head, and a bearing platform configured to mount a semiconductor substrate;
the control system comprises a detection module and a control module;
the detection module is disposed on the deposition apparatus, and is configured to detect whether a thickness defect exists in a deposited thin film on the semiconductor substrate or not; and
the control module is connected to the spraying head, and is configured to adjust a structure of an air outlet panel in the spraying head so as to adjust distances between air outlet holes in the air outlet panel and the deposited thin film.

11. The semiconductor deposition system according to claim 10, wherein the deposition apparatus further comprises a driving assembly;
the control module is connected to the spraying head through the driving assembly; and
the control module is configured to transmit a control signal to the driving assembly, and the driving assembly adjusts the structure of the air outlet panel in the spraying head based on the control signal, so as to adjust the distances between the air outlet holes in the air outlet panel and the deposited thin film.

12. The semiconductor deposition system according to claim 11, wherein the driving assembly is realized through a piezoelectric ceramic driver.

13. The semiconductor deposition system according to claim 11, wherein the deposition apparatus further comprises a blocking module connected to the driving assembly, and the driving assembly is configured to control the blocking module to block the air outlet holes in the spraying head or not based on the control signal.
